(19) United States
(12) Patent Application Publication
(10) Pub. No.: US 2020/0159980 A1
(43) Pub. Date: May 21, 2020

(54) Method for a computer-aided automated verification of requirements

(71) Applicant: Gerhard Schilling, Schrobenhausen (DE)

(72) Inventor: Gerhard Schilling, Schrobenhausen (DE)

(21) Appl. No.: 16/611,234

(22) PCT Filed: May 8, 2018
(86) PCT No.: PCT/EP2018/000246

§ 371 Date: Nov. 6, 2019

(30) Foreign Application Priority Data
May 8, 2017 (DE) 10 2017 004 348.5

(51) Int. Cl. G06F 30/33; G06F 11/36; G01R 31/3183; G06F 11/26

(52) U.S. Cl. CPC G06F 30/33; G06F 11/3604; G06F 11/261; G01R 31/318314; G01R 31/318307; G01R 31/318357

(57) ABSTRACT

In a method for the computer-aided, automated verification of requirements, the requirements are stored in a database, and at least one interface description and at least one functional description are filed, the requirement having at least one subcomponent. The verification includes the computer-aided verification of the completeness and/or consistency of the interface description and/or the functional description. The verification is done also in relation to subcomponents.

The invention relates to a method for the computer-aided automated verification of at least one requirement and for generating test data. A “requirement” here and below is understood as a description of any technical process. Thereby, it can be an electrical or electronic circuit, a hydraulic or pneumatic apparatus, a mechanical device, a production process, a chemical process or a computer software. This list is merely an example and not understood as being final. In particular, the above-mentioned examples may also occur in mixed or combined form in any way. Thereby, the requirement is intended to describe the specific technical process of a target system. In this way, the functionality of the target system is specified in its entirety. This requirement comprises at least one additional requirement as a subcomponent, wherein each of the requirements is stored in at least one database and comprises at least one interface description and one functional description.

In practice, various computer programs are known to collect requirements in text form and store them in a database. Thereby, this database is interlinked in order to use text passages elsewhere that are already in the database. For example, an interface description can be described as part of a signal processing component. If the signals associated with this interface are then needed elsewhere, the corresponding interface description can be linked to it. This has the advantage that a change in the interface description also affects the other linked components. The disadvantage, however, is that it is up to the developer whether he/she also uses this linking technique and how he/she handles a subsequently changing description. Thereby, the developer, usually consisting of a team with multiple members, can create incomplete or inconsistent requirements. Computer programs created with such poor requirements tend to be highly susceptible to errors, thereby causing the development process to be slow and last for a long time. However, in the absence of better systems, developers are forced to use these known components. Therefore, these form the prior art closest to the object of the invention.

The object of the invention is to create a method of the aforementioned type, which generates high-quality requirements and detects incompleteness or inconsistencies as early as possible.

According to the invention, this task is achieved by means of the following features.

In the case of the method according to the invention, at least one requirement is stored in a database. A database is a collection of blocks of data that are stored in one or a plurality of files and is configured for the one random access option. This requirement comprises at least one other requirement as a subcomponent, wherein this subcomponent must always be principally handled in the same way as the main component. However, it is not mandatory to include all specified subcomponents into this verification. It is quite conceivable to be able to specifically exclude individual subcomponents from the verification. In this way, the circumstance can be taken into account that different subcomponents still have not even been developed at a certain stage of development or that other developers are responsible for the corresponding subcomponent. If all subcomponents were inevitably involved in the verification, a large number of error messages would inevitably result in these cases, which significantly interfere with the development process. Each requirement comprises at least one interface description for at least one input and/or output signal and at least one functional description in formalized form. The interface description comprises all details concerning the respective interface and the signal that is received and/or sent via this interface. For example, this can include: Data width, range of values, protocol, associated physical value, sampling frequency, port mapping, initialization requirements and methods, filtering requirements and methods, averaging requirements and methods, and reliability indicators. However, this list is only an example and not understood as being final. The functional description is done in formalized form, for example, as a flowchart, state machine or pseudocode. This list is also only an example and not understood as being final. In order to detect gaps or errors in the requirement as early as possible, a computer-based verification for completeness or consistency is carried out. This verification includes the interface description and/or the functional description. In particular, the completeness verification of the interface description can be used to verify whether all the required information is included in the interface description. These depend in principle on the specified type of signal. Thus, purely binary signals are subject to considerably lower definition requirements than is the case for serially transmitted data or data transmitted in parallel. For example, if information is transmitted serially, the application of the respective protocol is crucial. In the case of pure state information, the signal immediately reflects an external system state so that, here, no protocol information is required. Reciprocal interdependencies are taken into account for checking the consistency of the interface description. For example, if a signal is marked as a serial stream in the interface description without specifying a corresponding protocol, this inconsistency can be detected and output as a warning or an error. Real-time requirements include information such as sampling rate, latency, and the required response time for a specific trigger event. It is also intended to verify whether the specified real-time requirements are consistent with each other. An inconsistency results, for example, from the fact that the response time of an interface description of an output signal is shorter than the sum of the associated sampling and processing times. Similarly, an inconsistency could be found due to violating the sampling theorem. This applies to both input as well as output signals. If the sampling or update rate is less than half the signal period, a proper signal processing is ruled out. In this case, a corresponding error or a warning is output. In the case of the interface description, it does not matter whether the interface concerns an external or internal hardware interface or a software interface. Software interfaces are usually data that are stored in a corresponding memory. These can be described and verified in the same way as hardware interfaces. The functional description describes the specific program sequence and therefore cannot be checked with the same thoroughness as the interface description. To a limited extent, however, completeness and consistency verifications are also possible. Because all of these verifications are computer-aided, documentation errors can be detected in the requirement before the first component of the target system is drawn or the first line of the software is written. In particular, it is thought that the interface description should be given an increased significance. This is done in particular by the fact that all signal-related information is stored exclusively in the interface descriptions. This prevents signal-related information from evading completeness or consistency verification. This results in a forced linking of the interface descriptions. If information about a signal is required at any point in the requirement, it can only come from the associated interface description. However, because this interface description is checked for completeness and consistency with high quality, definition errors and gaps are thus highly likely to be ruled out. Basically, this method forces the developer to think about all possible details early on before inconsistencies can arise. In this way, a target system with a high quality and a very short development cycle results, which improves overall development productivity significantly.

Preferably, the verification of the interface description includes checking whether certain information is stored, for example, whether the interface is to be initialized, filtered or verified. Often, complex signal processing is required, which is done by means of specialized components such as analogue-digital converters, frequency counters or other components for example. These components sometimes require initialization before the first value for the signal can be determined. For other interfaces, for example pure digital interfaces, initialization is often not necessary. Depending on the signal quality, it may also be necessary to filter the signal associated with the interface to eliminate interference pulses or increase signal accuracy. It must be expediently checked whether such information is included in the interface description in this respect so that a corresponding warning is output in the absence of such information. It may also be necessary to check a signal associated with the interface, for example, to determine its consistency or quality. The presence of this information is also expediently verified in order to prevent signals with poor quality or even irregular signals from being fed into further process handling.

In the event that the interface description requires initialization, filtering or verification, it is also appropriate to store the procedure required for this in the interface description. This is most expediently done by means of a corresponding functional description in formalized form. In this case, the method according to the invention checks whether a corresponding method is stored or whether corresponding parameters, for example, the number of required averaged values, are stored in order to filter the measurement value.

Often, signals have only a limited scope, wherein special handling must take place in the case of exceeding or falling below this scope. In order to set up these instances of special handling consistently across the entire requirement, it is useful to enter the scope of the signal in the interface description. The method according to the invention therefore checks whether a corresponding scope is defined. Basically, it is intended to store not only the scope but also intermediate values, in particular, limit values of the signal in the interface description. These limit values can then be used, for example, in the functional description for comparison with the signal. However, it is not expedient to check these limit values for completeness of the interface description since a verification based on objective criteria will fail. For such application scenarios, it is more appropriate to check the functional description to the effect that only parameters from interface descriptions are used as comparison parameters. This results in consistent use of the limit values.

As a rule, the signals obtained from interfaces must be stored in corresponding variables. These variables can then be referred to in the functional description, provided that it is ensured that the saving of the signals in the variable does not result in any loss of information. For this reason, the verification includes a comparison of the data width or algebraic sign of the interface description with the associated variable. If this comparison comes to the conclusion that information is lost when saving the signal in the variable, for example, because the data width is too small or a possible negative algebraic sign would be lost, a corresponding warning is generated.

By its very nature, the functional description is much more difficult to verify than the interface description since the functional description must reflect the algorithm used. It is difficult to find an error in an algorithm in a computer-aided manner. Nevertheless, certain verifications of the functional description are feasible. For example, it can be checked whether each state of the functional description is achievable due to defined state change conditions. If a state is not reachable, there is obviously an algorithmic error that results in a corresponding warning. It may well be that a state is only achievable when a signal leaves its scope in order to then perform a special handling routine in this state. However, if a state is only achievable due to conflicting signal conditions and/or physically unrealizable signals, there is obviously an algorithmic error in the functional description, which leads to a corresponding warning when verified by the method according to the invention.

In addition, it is advantageous to check whether a subsequent state is achievable from each state of the functional description. If a subsequent state was no longer reachable, the system would have to remain in this state forever so that the target system would be considered to have “crashed”. Thus, in the event that no subsequent state is achievable, there is an algorithmic error in the functional description that results in a corresponding warning due to the method according to the invention.

In addition, it is appropriate to check the functional description to see whether each defined signal of the interface description is used in the functional description. In the opposite case, the method according to the invention generates a corresponding warning. This warning indicates to the developer that he/she has either forgotten a signal in the functional description or should delete this signal from the interface description or mark it as “reserved”. In particular, this measure prevents the developer from basically listing all possible interfaces in the interface description of his/her requirement for reasons of comfort, which he/she could possibly require somewhere. However, the developer avoids the requirement to think about the required signals before creating the functional description. The method according to the invention then acknowledges this procedure with a corresponding number of warnings so that the developer must inevitably define a clean interface approach.

In particular, in the case of complex requirements, it increasingly occurs that output signals are inconsistent since various components of the requirement demand different values for the output signal. For example, if a component sets a certain output signal to one, if an input signal A is active and another component sets the same output signal to zero, if an input signal B is inactive, it may well happen that conflicting conditions for the output signal, in particular, when the input signal A is active and the input signal B is inactive. Such errors are very difficult to find in the finished target system and therefore cause a considerable increase in development time. It is therefore expedient to verify the uniqueness of the output signals or output signal changes already in the functional description and to acknowledge cases such as those mentioned above with a corresponding warning.

In computer science, recursive algorithms are known that provide a simple programmatic approach to solving a complex mathematical problem. However, such recursive approaches are highly dangerous in signal processing, as they assume that the corresponding input values remain constant. However, this is not the case with signal processing. For this reason, it is useful to check whether the functional description contains recursive signal queries. This can be determined in the easiest way by checking whether a state change condition in the functional description is dependent on a signal to be generated by the same functional description. Thus, recursive signal queries with corresponding warnings are acknowledged by the method according to the invention. However, a recursive algorithm without influencing states, such as fast analogue-to-digital conversion for example, is not affected.

In order to prevent important values, such as comparative values in condition change conditions for example, from being stored anywhere and thus taken from a completeness verification, it is advantageous if the method according to the invention checks state change conditions to see if values are used in them that are not stored in the interface description. This forces the developer to store all the comparison values he/she needs for his/her functional description in the interface description, where it can then be checked for consistency throughout the requirement.

On the other hand, in order to prevent the developer from simply defining all possible values in the interface description that he/she might need for the sake of prevention, it is useful to check whether the defined values in the functional description. Superfluous values of the interface description then generate a corresponding warning. For example, it can occur that, in addition to a completely processed signal, a raw signal form should be stored, for example, the unfiltered signal. In the event of an unexpected fault event, the time progression of the raw signal can be read out from this memory in order to find indications for detecting the fault event early on. This information is of considerable importance for the further development of the target system, in particular, for safety-relevant components such as aircraft or power plant components. However, in order to be able to feed the raw signal to a data logger, it must be available for the data logger component. The easiest way to do this is to list it in the interface description. However, this also clearly documents that different components receive different processing stages of the signal, thereby eliminating confusion. Verifying the use of the raw signal in the functional description also ensures that the developer does not generally make all possible processing stages in the interface description publicly available, because in this way he/she is using would be overwhelmed by a large number of warnings.

It is also appropriate to check the functional description to see whether a calculated value is used before it is overwritten. As a rule, overwriting a value before reading it out is an algorithmic error, so a corresponding warning is created here.

It is often necessary to define different modes in a requirement in which the target system to be created should work differently. For example, these modes can include: Normal operating mode, undervoltage mode, defective sensor mode, defective actuator mode, insufficient storage mode, etc. In addition or as an alternative, modes can also be used for different embodiments of the requirement, for example for different application models can be defined. Thus, a particular component for a motor vehicle may have different modes for different vehicle models, so that the adaptation to a particular vehicle model can be carried out by simple choice of mode. The different modes can also be used in combination. For example, two modes can be used for the operating voltage, two modes for the state of the sensors, two modes for the state of the actuators, and four modes for the models. This results in 32 different modes. In reality, the modes can become much more complex, which significantly increases their accumulated number. In the case of such requirements, it is relatively difficult to clearly determine whether a particular functional description is also actually uniquely associated with the different modes. However, this unique assignment is an essential prerequisite for a correctly running target system. For this reason, it is appropriate to check whether it is clearly defined for each defined mode whether at least one of the functional descriptions is to be executed. When definition gaps regarding the mode selection occur, a corresponding warning is generated.

When defining modes, it is relatively common to overlook possible mode changes. It may well happen that certain mode changes can be excluded. Typically, however, an undefined mode switch is an indication of an incomplete requirement. For this reason, it is useful to check whether any other mode is reachable from each mode or whether its accessibility is explicitly denied. The latter allows to suppress a corresponding warning if a particular mode transition is not provided. In this case, however, an explicit denial is required in such a way that the developer must have thought about the undefined mode change. However, this does not prevent an accidental omission of a particular mode change.

The invention also relates to a method for the computer-aided automated generation of test data for a target system, which is intended to meet a requirement. In prior art, a large number of test data is generated between the defined limits of the scope of the individual signals in order to test the generated target system. However, in the case of requirements which are verified according to the method according to the invention, it is ensured that—provided that warnings are observed—all threshold values for comparison with signals are stored in the interface descriptions. This means that all limit values where the behaviour of the target system changes in any way are clearly defined by values specified in the interface descriptions. This is used in the method according to the invention for the automated generation of test data in such a way that the interface descriptions of all input signals are analysed, wherein all values entered in the interface description of each input signal are sorted. The basic behaviour of the target system does not change between adjacent values of this sorted series of values. Therefore, it is sufficient to generate a test value between these recorded values and to output these values as test data in different permutations. This generates much less test data, wherein it is ensured that each query condition of the signals is implemented in the test data. This not only speeds up the test of the target system, but also speeds up the system.

The method according to the invention is preferably used for requirements that are used to control and/or regulate at least one technical process. There, relatively high demands on the safety of the target system must be placed so the method according to the invention has a particularly beneficial effect in this area.

Preferably, the target system software is implemented, which runs on at least one controller, which, in addition to the central computing unit, also has memory units and interfaces. In this area, which is also referred to as the “embedded system”, particularly high requirements apply to software security, since it is usually not possible to interfere with the software externally.

The method according to the invention is explained in more detail as an example and in extracts without claim to completeness on the basis of the following exemplary embodiments with reference to the drawing. These embodiments serve to explain the method according to the invention and not to determine the scope of protection defined by the claims.

The figures show:

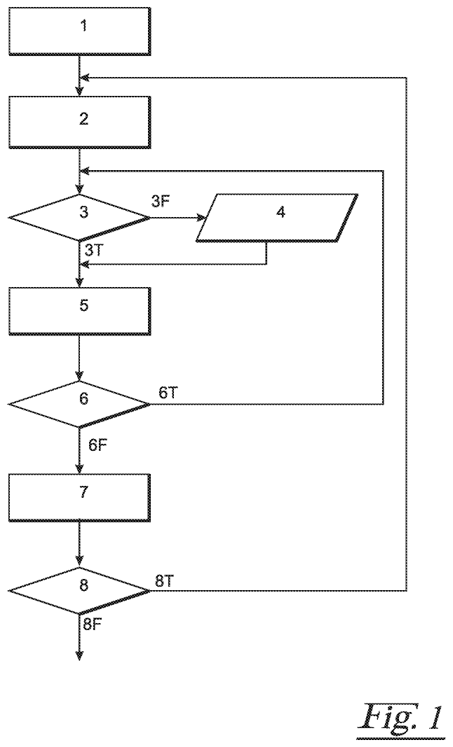

FIG. 1 a method for checking the interface description for completeness,

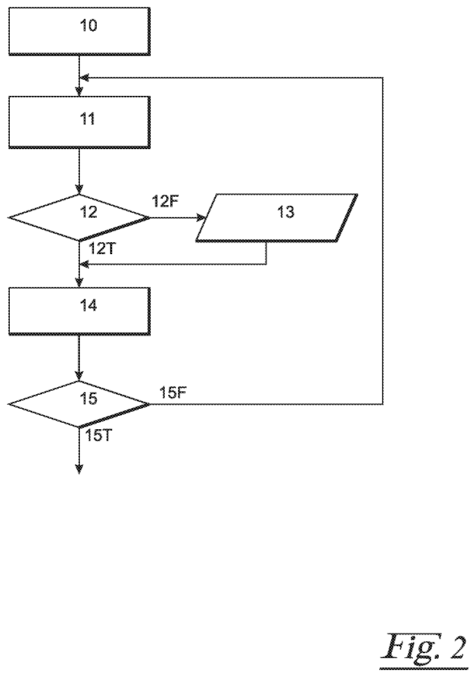

FIG. 2 a method for checking the functional description for accessibility of all states,

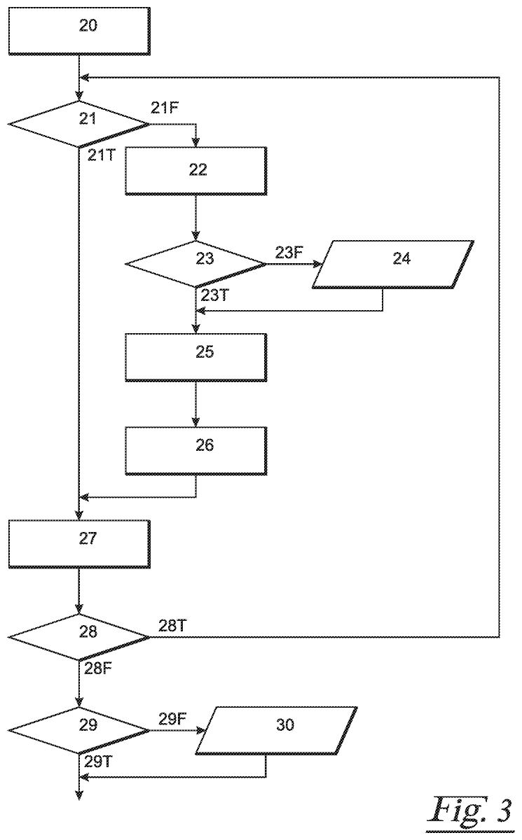

FIG. 3 a method for implementing a state function,

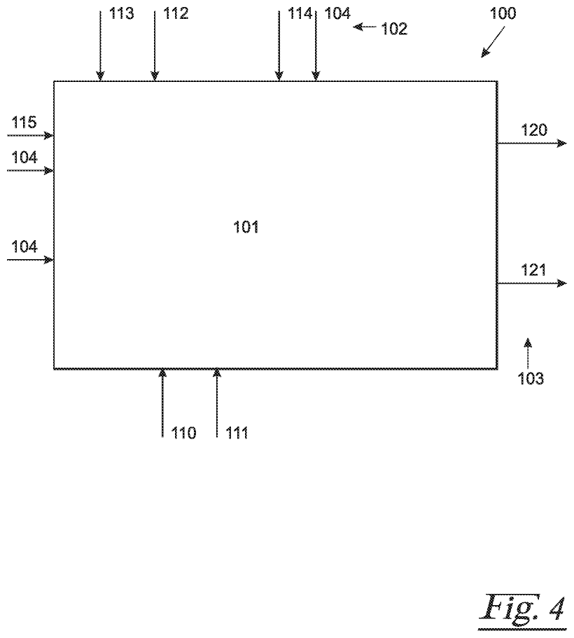

FIG. 4 a formalized requirement of a radio as a functional black box architecture and

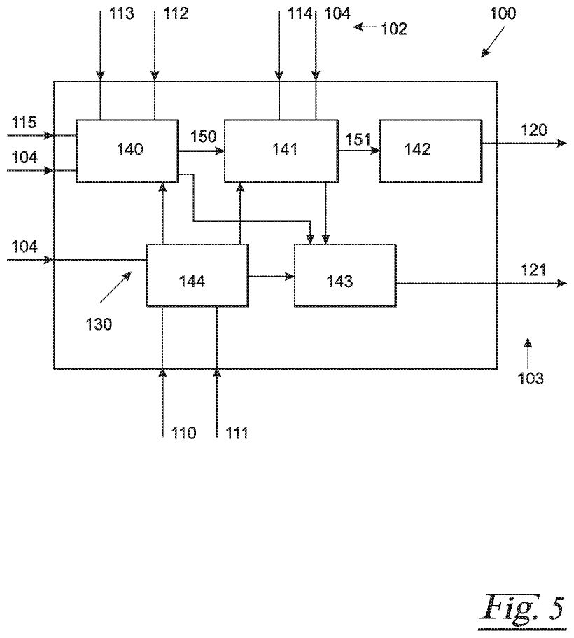

FIG. 5 the requirement in accordance with FIG. 4 with components.

FIG. 1 shows an algorithm for checking the interface description for completeness. This assumes that the developer has been provided with a template for creating an interface description in a database that contains corresponding fields to be filled in. The algorithm in accordance with FIG. 1 checks the interface descriptions stored in the database in the following way:

At step 1, a count variable n is initialized to the value 0. This count variable n is used to reference the interface descriptions. This means that the first interface description can be referenced with n=0, the second interface description with n=1, and so on. At step 2, another count variable m is initialized to the value 0. This count variable m is used to reference the individual data fields within the interface description, wherein the first data field is referenced with the index m=0.

At step 3, it is queried whether a value is entered in the database for interface description n in the field m. In addition, step 3 queries whether the entered value in the database is also consistent with the other values of the interface description n. If at least one of the tests above fails, the query branches off to branch 3F in accordance with step 3. In this case, a corresponding warning is generated and output at step 4. If there are no objections found during the tests in accordance with step 3, branch 3T is used, thereby suppressing the output of the alert at step 4.

At step 5, the count variable m is incremented to address the next field within the interface description n. At step 6, it is queried whether the count variable m is still within permitted predefined limit values. If this is the case, there is a branching off to branch 6T so that the program flow continues with step 3. However, if the count variable m is within the allowed range, there is a branching off to branch 6F and the following step 7 is carried out.

At step 7, the count variable n is incremented to address the next interface description.

In the following step 8, it is queried whether the count variable n is still within permissible predefined limit values. If this is the case, there is a branching off to branch 8T so that the program flow continues with step 2. However, if the count variable m is within the allowed range, there is a branching off to branch 8F and the following step is carried out.

After passing through this algorithm, all interface descriptions are checked for completeness and consistency. As you can see, the verification of the interface description is relatively simple in terms of program technology, wherein, nevertheless, a very high test quality can still be achieved. This simplification is a consequence of separating the entire requirement into a functional description and interface description.

FIG. 2 shows an algorithm for checking the functional description. It is assumed that the functional description in the form of a state machine is stored in the above-mentioned database.

At step 10, the function state (init) is called up. This function puts a virtual state machine in the state in which the state machine comes, for example, immediately after a reset. This is therefore the initial state of the state machine. In addition, this function performs various verifications, which are explained below.

At step 11, a count variable n is initialized to 0. This assumes that the individual states of the state machine in the database can be retrieved initiated via the count variable n.

At step 12, it is checked if the checked flag has been set for the state n. If this is not the case, the query branches off into branch 12F in accordance with step 12 and, at step 13, generates a corresponding warning, which is output. However, if the checked flag was set, the query branches into branch 12T in accordance with step 12 and suppresses the output of the warning by bypassing step 13.

At step 14, the count variable n is incremented to call the next following state.

The query in accordance with step 15 now checks whether the count variable n is within permissible limits or whether n references a state that no longer exists. If the count variable n is allowed, the query branches to the branch 15T in accordance with step 15 so that the program flow branches to step 12. However, if the n count variable is invalid, the verification is complete.

FIG. 3 shows the algorithm for the state function in accordance with step 12. It is to be understood that step 10 is formed in the same way.

At a step 20, a count variable m is initialized to 0. This count variable m references a corresponding state change condition for the respective selected state, including a reference to the respective subsequent state. At a step 21, it is queried whether a checked flag of the selected state is set. In this case, the program flow continues in branch 21T. However, if the checked flag has not been set, branch 21F continues. Thereby, it must be considered that the checked flag of each state is reset at the beginning of the described algorithm. Setting this checked flag indicates that this state has already been checked and therefore can be omitted from further verification. Endless loops are avoided in this way. It also significantly increases the efficiency of the algorithm by reliably excluding duplicate and multiple verifications of the same state.

Step 22 is carried out from branch 21F, in which the checked flag has been set. This indicates that the current state has now been subject to verification and that re-verification is to be ruled out.

In the following step 23, one or a plurality of queries are made regarding the state, which are concerned with completeness and consistency in particular. In the event of inconsistencies or incompleteness, there is a branching off to branch 28F and a warning is issued at step 24. Otherwise, step 24 is suppressed by selecting branch 24T.

At the following step 25, an indicator of the transition condition is read with the index m and, at step 26, the function state with the indicator determined in this way is called up as a parameter. This results in a recursive call to the state function to ensure that all possible states and state transitions are taken into account.

At step 27, the count variable m is incremented to check the next transition condition.

At step 28, it is queried whether the count variable m is still within permitted limits. If this is the case, there is a branching off to branch 28T so that step 21 is executed again. However, if the count variable m references an invalid state, there is a branching off to branch 28F and the query is carried out in accordance with step 29. This query in accordance with step 29 checks whether the count variable m has reached a value of >1. If this is the case, the state function is terminated by selecting the branch 29T. Otherwise, branch 29F is selected and, at step 30, it generates a warning that no subsequent state is achievable.

The process of this algorithm is relatively complex due to the recursive call of the state function, but is otherwise very difficult to implement. The state function starts with the initial state in accordance with step 10 and checks it according to the specified criteria. In the event that the condition has already been checked, all verifications, including calls to subsequent states, are suppressed. The recursive algorithm initially goes through the states in the order of the first transition condition specified in each state until either no subsequent state can be found or a state that has already been checked is called up. The last selected transition condition of the state machine is then changed to the transition condition specified in the database and the algorithm is executed in the same way. As a result, the individual transition conditions of the initialization state are usually processed last.

FIG. 4 shows a requirement for a radio in the black box display. The individual interfaces that ensure the connection of the device to the outside are specified, but the internal sequence remains largely unspecified.

Requirement 100 comprises a black box 101, input interfaces 102, output interfaces 103, and interference 104. The processing of the signals entering from the input interfaces 102 in order to generate the signals of the output interfaces 103 are reserved for the unspecified black box 101.

The input interfaces 102 comprise a power supply 110, an on/off switch 111, a frequency band switch 112, a frequency selector 113 and a volume selector 114. In addition, the input interface 102 comprises an antenna connection 115, via which electromagnetic waves can be received.

The output interface 103 includes a loudspeaker 120 and light-emitting diodes 121 for function control. Potential disturbances 104 must be taken into account for supply voltage fluctuations, electromagnetic foreign radiation and temperature influences.

At this black box level, the functional relationship between the individual signals is not specified. The completeness verification of this requirement is therefore usually limited to a completeness verification of the interface descriptions at this level. This means that, for all input interfaces 102 and output interfaces 103, the respective signals must be fully described in order to pass a completeness verification according to the invention. In the case of switching functions, voltage level definitions as well as maximum current load capacity are generally sufficient. In the case of antenna input 115, on the other hand, transmission protocols and modulation modes must also be specified in order to make the target system functionally safe.

If an interface is not fully defined in this stage of development of the target system, this may result in contradictions in the course of development and subsequent development, which prevent the proper functioning of the target system. These contradictions may, in principle, cause a developer of a subcomponent to assume certain conditions at the input signal that are not applicable. In the field of digital electronics in particular, it is often assumed that all input signals follow the level definition of the TTL logic, unless otherwise specified. In the case of analogue devices, such assumptions are usually not made. For example, if the frequency band selector 112 switches between 0 volts and 12 volts, but the subcomponent that is supposed to evaluate this signal originates from TTL levels however, this can lead to the destruction of the electronic components. Due to such considerations, it is important to present all interface descriptions in full. In order to ensure the functionality of the target system, it is therefore expedient to check these interface descriptions with the method according to the invention so that appropriate warnings or error messages are generated in case of specification gaps. These indicate to the developer that he/she has created an incomplete interface description, which must be improved accordingly.

FIG. 5 shows the requirement in accordance with FIG. 4 with the subcomponents it contains. In addition to the already described interface description, a functional description of the black box 101 in accordance with FIG. 4 is inserted. This functional description includes various subcomponents 130, which in turn exchange signals. In accordance with this, the individual subcomponents 130 require interface descriptions again. Various subcomponents 130 use external interfaces of requirement 100. Since these are already fully defined, any further definition necessity is eliminated.

However, the subcomponents 130 also exchange signals with each other. For this purpose, the subcomponents have 130 internal interfaces 131, which, in turn, must be specified accordingly. The interface descriptions of the subcomponents 130 are checked for completeness in the same way. However, it is possible to exclude individual subcomponents 130 from this completeness verification if these subcomponents 130 have not yet been developed at a certain stage of development or if the development of these subcomponents in the other developers. In this way, the resulting flood of errors and warnings due to the incomplete interface description can be contained. It is to be understood that the completeness verification should also be extended to this originally excluded subcomponents 130 at a correspondingly advanced point during development.

The requirement 100 in accordance with FIG. 5 contains in the functional description a tuner 140, an amplifier 141, a loudspeaker 142, an LED control 143 and a power supply 144.

The tuner 140 is connected to the antenna connector 115 and the frequency band selector 112. In addition, it is to be expected that an interference feed 104 occurs in the form of electromagnetic waves. This interference radiation must be suppressed accordingly by the tuner 140. The tuner 140 generates a low-frequency signal 150, for which a corresponding interface description at the subcomponent level is to be created. The amplifier 141 accepts this low-frequency signal 150, so that for the amplifier 141 no separate interface description is required in this regard. Rather, reference is made to the interface description of the tuner 140. The completeness verification of the interface descriptions ensures that the interface descriptions of the subcomponents are consistent and that different interface descriptions are not inadvertently stored for one and the same signal. This clearly determines which low-frequency signal the tuner must provide 140 and what the amplifier 141 receives.

The amplifier 141 is connected to the loudspeaker 142. For this purpose, the amplifier 141 generates a reinforced signal 151, which is suitable for loudspeaker control. Also for this purpose, a corresponding interface description must be stored in order to pass the completeness verification. The LED control 143 is connected to the tuner 140, the amplifier 141 and the power supply 144. Also with regard to this, corresponding interface descriptions must also be created in this respect, which enable the proper signal processing by the LED control 143 to take place. The power supply 144 supplies all other subcomponents 130 with the required voltages. For this purpose as well, corresponding interface descriptions must be stored, which can be limited to voltage values, tolerances and current carrying capacities.

By means of the completeness verification according to the invention, it is achieved that potential sources of error in the development of the corresponding target system are detected at an early stage and that the target system as a whole is defined consistently in itself. This reduces errors in the target system, making its technical functionality more reliable.

The same goal could also be achieved in principle by including monitoring and redundancy components. However, these only shift the problem to another level, especially since these components must also function correctly. In particular, if there is a misunderstanding in the interface definition, monitoring components would also usually fail. Thus, the proposed approach of verifying the relevant requirements solves the task set much more efficiently and reliably and ensures a well-functioning target system.

1. A method for a computer-aided automated verification of at least one requirement, which comprises at least one other requirement as a subcomponent, wherein the requirements are stored in at least one database and comprise at least one interface description for at least an input and/or an output signal and at least one functional description in formalized form, characterized in that the verification includes a computer-aided verification of the completeness and/or the consistency of the interface description and/or the at 3t one functional description and the specified verification also extends to at least one of the other requirements.

2. The method according to claim 1, characterized in that the verification comprises whether an interface specified in the at least one interface description must be initialized and/or whether the signal must be filtered and/or verified.

3. The method according to claim 2, characterized in that the verification comprises how an interface specified in the at least one interface description must be initialized and/or whether the signal must be filtered and/or verified.

4. The method according to claim 1, characterized in that the verification comprises if a scope of the signal specified in the interface description has been defined.

5. The method according to claim 1, characterized in that the verification comprises whether a data width and/or an algebraic sign between an interface specified in the interface description and one of the variables associated with the interface are compatible.

6. The method according to claim 1, characterized in that the verification comprises whether each state of the functional description can be achieved due to the defined state change conditions.

7. The method according to claim 1, characterized in that the verification comprises whether a subsequent state can be achieved from any state of the at east one functional description.

8. The method according to claim 1, characterized in that the verification comprises whether each state change condition of the at least one functional description selects a clear subsequent state.

9. The method according to claim 1, characterized in that the verification comprises whether each signal of the interface description is used in the at least one functional description.

10. The method according to claim 1, characterized in that the verification comprises whether each output signal or output signal change defined in the interface description has been clearly defined by the states defined in the at east one functional description.

11. The method according to claim 1, characterized in that the verification comprises whether the at least one functional description defines at least one dependency of a state change condition on a signal, which should be generated in the same functional description.

12. The method according to claim 1, characterized in that the verification comprises whether the at east one functional description defines at least one state change condition, which uses at least one value, which has not been defined in the associated interface description.

13. The method according to claim 1, characterized in that the verification comprises whether values defined in the interface description are used in the at east one functional description.

14. The method according to claim 1, characterized in that the verification comprises whether a calculated value is used before the calculated value is overwritten.

15. The method according to claim 1, characterized in that the at least one functional description defines various modes and the verification comprises whether the verification has been clearly defined for each mode if at least one of the functional descriptions is to be carried out.

16. The method according to claim 15, characterized in that the verification comprises whether any other mode is achievable from each mode or accessibility of any other mode is expressively denied.

17. A method for the computer-aided automated generation of test data for a target system, which should fulfil a requirement, which is stored in a database and comprise at least interface descriptions and at least one functional description in formalized form, characterized in that interface descriptions of all input signals are analysed, wherein all values of each input signal, which are listed in the interface description, are sorted in order to generate test values, which are between these listed values and different permutations of these test values are output as test data.

18. The method according to claim 17, characterized in that the requirement relates to a software, is the software being provided for controlling and/or regulating at least one technical process.

19. The method according to claim 18, characterized in that the software runs on at least one controller.

20. The method according to claim 1, characterized in that the at least one requirement relates to a software, is the software being provided for controlling and/or regulating at least one technical process.
